(19) United States
(12) Patent Application Publication
(10) Pub. No.: US 2010/0054033 A1
(43) Pub. Date: Mar. 4, 2010

(54) MAGNETIC THIN LINE AND MEMORY DEVICE

(75) Inventors: Takao Ochiai, Kawasaki (JP); Hiroshi Ashida, Kawasaki (JP); Keiichi Nagasaka, Isehara (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/543,926

(22) Filed: Aug. 19, 2009

(30) Foreign Application Priority Data
Sep. 4, 2008 (JP) 2008-226661

(51) Int. Cl. G11C 11/14

(52) U.S. Cl. 365/171; 428/829

(57) ABSTRACT

A magnetic thin line includes a first magnetic film having in-plane magnetic anisotropy and a second magnetic film that is magnetically coupled to the first magnetic film and has perpendicular magnetic anisotropy. With the coupling of the first magnetic film and the second magnetic film, magnetic wall width of the first magnetic film is lower than a case where the first magnetic film is not magnetically coupled to the second magnetic film.

### CROSS-REFERENCE TO RELATED APPLICATION

This application is based upon and claims the benefit of priority of the prior Japanese Patent Application No. 2008-226661, filed on Sep. 4, 2008, the entire contents of which are incorporated herein by reference.

### FIELD

A certain aspect of embodiments relates to a magnetic thin line and a memory device.

### BACKGROUND

An extremely large capacity non-volatile memory of next generation alternative to an existing DRAM (Dynamic Random Access Memory) or a flash memory is being developed actively. A candidate may be a FeRAM (Ferroelectric Random Access Memory) using a dielectric material, a PRAM (Phase change RAM) using a phase changing of insulator composing a memory, a MRAM (Magnetoresistive Random Access Memory) using TMR (Tunnel Magnetic Resistance) effect, or a RRAM (Resistive RAM) operating with unidentified principle and using large resistance changing caused by applying direction of a pulse current. The candidates have advantages and disadvantages and are not developed enough to be replaced with the existing memory.

U.S. Pat. No. 6,834,005 suggests a racetrack memory having high capacity with use of magnetic wall movement by spin injection disclosed in A. Yamaguchi et al., Phys. Rev. Lett., 92, 077205 (2004) and the TMR effect. The present applicant reviews a storage memory using the above-mentioned two phenomena/effect as disclosed in Japanese Patent Application Publication Nos. 2007-324269, 2007-324172, and 2007-317895.

### SUMMARY

According to an aspect of the present invention, there is provided a magnetic thin line including a first magnetic film having in-plane magnetic anisotropy and a second magnetic film that is magnetically coupled to the first magnetic film and has perpendicular magnetic anisotropy. With the coupling of the first magnetic film and the second magnetic film, magnetic wall width of the first magnetic film is lower than a case where the first magnetic film is not magnetically coupled to the second magnetic film.

According to an aspect of the present invention, there is provided a memory device including a magnetic thin line that has a first magnetic film having in-plane magnetic anisotropy and a second magnetic film that is magnetically coupled to the first magnetic film and has perpendicular magnetic anisotropy, a recording element that records information in the magnetic thin line, and a re-generating element that re-generates the information recorded in the recording element. With the coupling of the first magnetic film and the second magnetic film, magnetic wall width of the first magnetic film is lower than a case where the first magnetic film is not magnetically coupled to the second magnetic film. The information is recorded or re-generated by shifting a magnetic wall separating magnetic sections formed in the magnetic thin line with electrical current.

### BRIEF DESCRIPTION OF DRAWINGS

FIG. 1 illustrates a schematic perspective view of a magnetic memory device in accordance with an embodiment;

FIG. 2 illustrates a perspective view of a recording region and a reserving region;

FIG. 3 illustrates a cross sectional view of a magnetic memory device;

FIG. 4A and FIG. 4B illustrate material of a magnetic thin line; and

FIG. 5A illustrates temperature at which magnetic anisotropy of Gd₂₀Fe_{68.2}Co_{11.8} is changed from perpendicular to in-plane; and

FIG. 5B illustrates temperature dependence of coercive force (Hc) of Gd₂₀Fe_{68.2}Co_{11.8}.

### DESCRIPTION OF EMBODIMENTS

There are some problems in the development of the magnetic wall movement type of storage device. The most important problem is to reduce current (magnetic wall driving current) necessary for movement of a magnetic wall of a magnetic thin line for recording data.

For example, M. Hayashi et al., Phys. Rev. Lett., 97, 207205 (2006), S. S. P. Parkin et al., Science 320, 190 (2008), and M. Hayashi, et al., Science 320, 209 (2008) disclose that current value gets to 3×10¹² A/m² when a conventional magnetic thin line (magnetic thin line made of NiFe single layer, an in-plane magnetic anisotropy film) and a high radiation performance substrate, and current necessary for driving the magnetic wall with a high speed (nano seconds) pulse voltage is estimated. The same result as the above documents are obtained when the present inventors conduct the same examination.

However, it is preferable that the magnetic wall driving current is reduced by more than one digit compared to the estimated magnetic wall driving current in order to make the magnetic wall movement type of storage device using a magnetic thin line, in view of heating of the magnetic thin line, vibration of an interconnection for providing a current to the magnetic thin line or the like.

The present inventors has earnestly studied a method of reducing current (magnetic wall driving current) for driving a magnetic wall of a magnetic thin line. And, the present inventors has reached a conclusion that the magnetic wall driving current may be reduced with use of a relation between a threshold current density required for magnet wall driving and magnetic wall width and a relation between the magnetic wall width and uniaxial magnetic anisotropy. And, with the study, the present inventors have had knowledge that the magnetic wall width may be reduced and the magnetic wall driving current may be reduced by enlarging the uniaxial magnetic anisotropy.

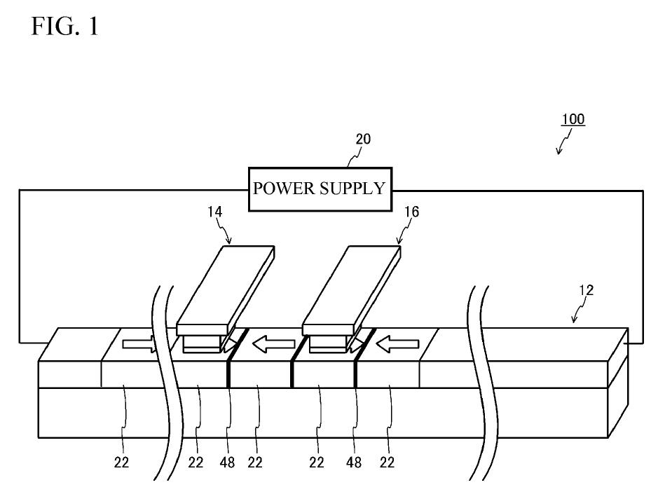

A description will be given of a magnetic memory device 100 acting as a memory device in accordance with an embodiment with reference to FIG. 1 through FIG. 5B.

FIG. 1 illustrates a schematic perspective view of the magnetic memory device 100 in accordance with the embodiment. The magnetic memory device 100 has a magnetic thin line 12, a recording element 14, a re-generating element 16, a power supply 20 acting as a current providing portion providing current to the magnetic thin line 12, as illustrated in FIG. 1.

The magnetic thin line 12 has a plurality of magnetic sections 22 separated by a physical insection. Information “1” and “0” are recorded with magnetization direction of each magnetic section 22 (an arrow direction of FIG. 1). The magnetic thin line 12 actually has a few hundreds to a few ten thousands magnetic sections 22. If magnetization directions of adjacent magnetic sections 22 are oriented in oppositely direction in the magnetic thin line 12, a magnetic wall 48 is generated between the adjacent magnetic sections 22. In contrast, if magnetization directions of adjacent magnetic sections 22 are oriented in the same direction, the magnetic wall 48 is not generated between the adjacent magnetic sections 22. The magnetization directions are oriented in oppositely direction through the magnetic wall 48, as a general characteristic of ferromagnetic material.

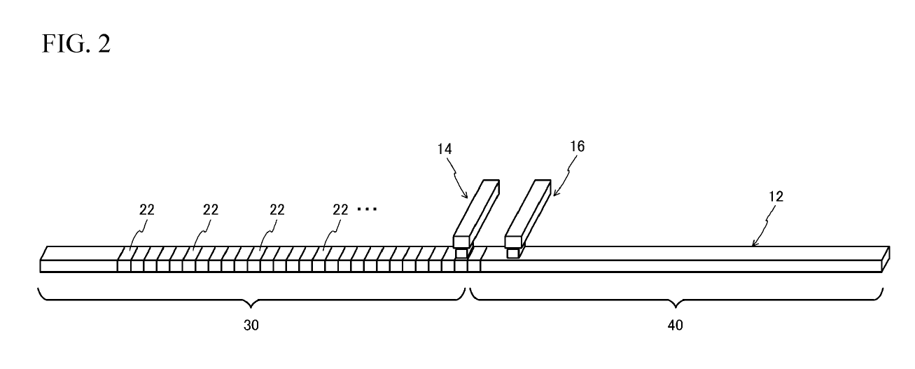

The magnetic thin line 12 is actually divided into a recording region 30 recording information and a reserving region 40 other than the recording region 30, as illustrated in FIG. 2. The information is recorded in the magnetic section 22 of the recording region 30. Details of the material of the magnetic thin line 12 is described later.

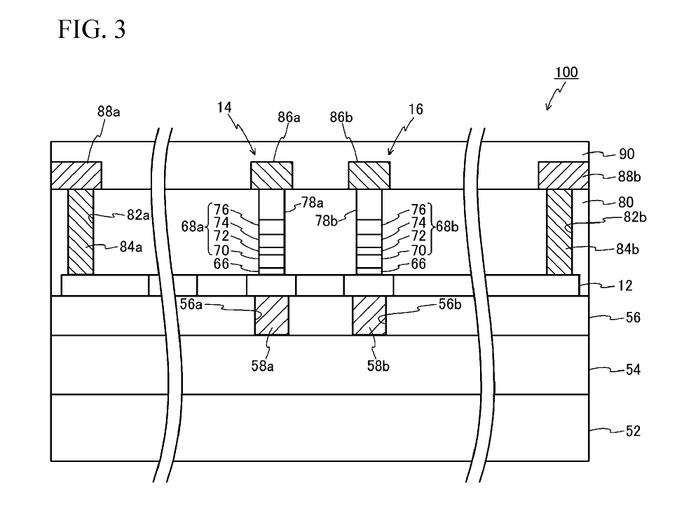

FIG. 3 illustrates a specific cross sectional view of the magnetic memory device 100 illustrated in FIG. 1. The magnetic thin line 12 is formed on a region, the region being composed of a silicon substrate 52, an interlayer insulating film 54 formed on the silicon substrate 52, and an interlayer insulating film 56 formed on the interlayer insulating film 54, as illustrated in FIG. 3.

The silicon substrate 52 may have a transistor or the like.

Grooves 56a and 56b are formed in the interlayer insulating film 56. A lower electrode 58a of the recording element 14 is implanted in the groove 56a. A lower electrode 58b of the re-generating element 16 is implanted in the groove 56b. The lower electrodes 58a and 58b are electrically coupled to the transistor on the silicon substrate 52.

A fixed-magnetic layer 68a having a laminated ferri structure is formed on an area facing with the lower electrode 58a through the magnetic thin line 12 and a barrier layer 66 made of MgO. A fixed-magnetic layer 68b having a laminated ferri structure is formed on an area facing with the lower electrode 58b through the magnetic thin line 12 and the barrier layer 66.

The fixed-magnetic layers 68a and 68b have a lamination structure in which a ferromagnetic layer 70 made of CoFeB, a non-magnetic layer 72 made of Ru, a ferromagnetic layer 74 made of CoFe, and an antiferromagnetic layer 76 made of PtMn are laminated in order. Connection electrodes 78a and 78b made of Ta are respectively formed on the fixed-magnetic layers 38a and 38b.

An interlayer insulating film 80 is formed on a face of the interlayer insulating film 56, on which the magnetic thin line 12, the fixed-magnetic layers 68a and 68b, and the connection electrodes 78a and 78b are formed, so that an upper face of the connection electrodes 78a and 78b is exposed. Contact holes 82a and 82b reaching each end part of the magnetic thin line 12 are formed in the interlayer insulating film 80. Contact plugs 84a and 84b are implanted in the contact holes 82a and 82b respectively.

An upper electrode 86a, an upper electrode 86b, and interconnections 88a and 88b are formed on the interlayer insulating film 80. An interlayer insulating film 90 is formed on the interlayer insulating film 80 so as to implant the upper electrodes 86a and 86b and the interconnections 88a and 88b.

The recording element 14 for recording information in the magnetic sections 22 of the magnetic thin line 12 is formed with the lower electrode 58a, the barrier layer 66, the fixed-magnetic layer 68a, the connection electrode 78a and the upper electrode 86a. The re-generating element 16 for reading the information recorded in the magnetic sections 22 of the magnetic thin line 12 is formed with the lower electrode 58b, the barrier layer 66, the fixed-magnetic layer 68b, the connection electrode 78b and the upper electrode 86b.

The interconnections 88a and 88b are electrically coupled to a first end part and a second end part of the magnetic thin line 12 through the contact plugs 84a and 84b respectively. Further, the interconnections 88a and 88b are electrically coupled to the power supply 20 illustrated in FIG. 1.

In the magnetic memory device 100, the magnetic wall 48 is movable with a spin torque generated when electrical current (pulse current) flows in the magnetic thin line 12 in a longitudinal direction thereof. It is therefore possible to shift the information recorded in the magnetic section 22. For example, electrical spin flows to the right and the magnetic wall 48 moves to the right when the electrical current flows to the left in FIG. 2. The electrical spin flows to the left and the magnetic wall 48 moves to the left when the electrical current flows to the right in FIG. 2.

The magnetic section 22 moves from the recording region 30 to the reserving region 40 and moves to the position facing with the recording element 14 with the above-mentioned movement when information is to be recorded in the magnetic memory device 100. The magnetic section 22 moves from the recording region 30 to the reserving region 40 and moves to the position facing with the re-generating element 16 with the above-mentioned movement when information is to be read from the magnetic memory device 100.

Information is written (recorded) to the magnetic section 22 of the magnetic thin line 12 by setting the magnetization direction of the magnetic section 22 of the magnetic thin line 12 to be the same direction as the magnetization direction of the fixed-magnetic layer 68a (first direction) or the opposite direction of the magnetization direction of the fixed-magnetic layer 68a (second direction).

In concrete, the electrical potential of the lower electrode 58a is set to be higher than that of the upper electrode 86a when the magnetization direction of the magnetic section 22 of the magnetic thin line 12 is reversed from the second direction to the first direction. Thus, electrical current is flown vertically to the film face from the magnetic thin line 12 to the fixed-magnetic layer 68a, spin-polarized conductive electron is flown from the fixed-magnetic layer 68a to the magnetic thin line 12, and the spin-polarized conductive electron is exchange-interacted with an electron of the magnetic thin line 12. This results in torque generation between the electrons. The magnetization direction of the magnetic section 22 of the magnetic thin line 12 is reversed from the second direction to the first direction, when the torque is sufficiently large.

On the other hand, the electrical potential of the upper electrode 86a is set to be higher than that of the lower electrode 58a when the magnetization direction of the magnetic section 22 of the magnetic thin line 12 is to be reversed from the first direction to the second direction. Thus, the magnetization direction of the magnetic section 22 of the magnetic thin line 12 is reversed from the first direction to the second direction with an effect contrary to the above-mentioned effect.

On the other hand, the information written (recorded) in the magnetic section 22 of the magnetic thin line 12 is read (re-generated) by detecting resistance between the upper electrode 86b and the lower electrode 58b composing the re-generating element 16. In concrete, the resistance between the lower electrode 58b and the upper electrode 86b is high when the magnetization direction of the fixed-magnetic layer 68b is opposite to the that of the magnetic section 22 facing with the fixed-magnetic layer 68b. In contrast, the resistance between the lower electrode 58b and the upper electrode 86b is low when the magnetization direction of the fixed-magnetic layer 68b is the same as that of the magnetic section 22 facing with the fixed-magnetic layer 68b. The resistance may be related to data “0” and “1” because the resistance indicates high and low. Therefore, it is possible to determine whether the information written to the magnetic section 22 of the magnetic thin line 12 is “1” or “0”.

A description will be given of the material of the magnetic thin line 12.

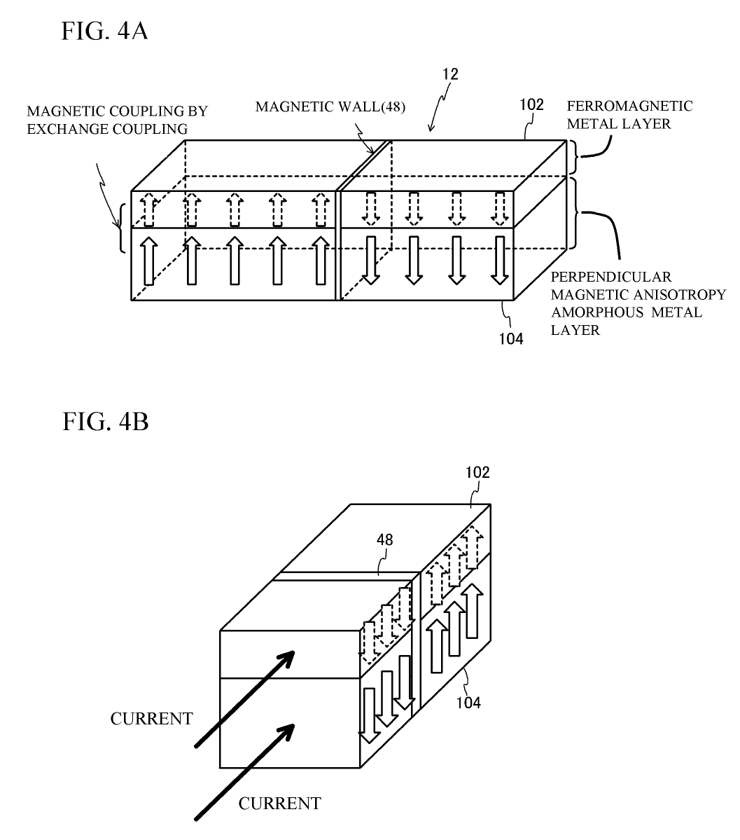

In the embodiment, the magnetic thin line 12 has a lamination structure in which a first magnetic film 102 and a second magnetic film 104 are laminated, as illustrated in FIG. 4A. The first magnetic film 102 is made of a ferromagnetic metal layer having in-plane magnetic anisotropy. The second magnetic film 104 is made of an amorphous metal layer having perpendicular magnetic anisotropy. As illustrated in FIG. 4B, the electrical current (current for driving the magnetic wall) is provided to both the first magnetic film 102 and the second magnetic film 104, when the magnetic wall of the magnetic thin line 12 is moved.

The ferromagnetic metal layer of the first magnetic film 102 is made of alloy including at least one of Fe, Ni and Co, or is made of the alloy in which at least one of Al, Cu and Si, non-magnetic metal, is doped. The first magnetic film 102 (the ferromagnetic metal layer) has a thickness lower than that of the second magnetic film 104 (the amorphous metal layer).

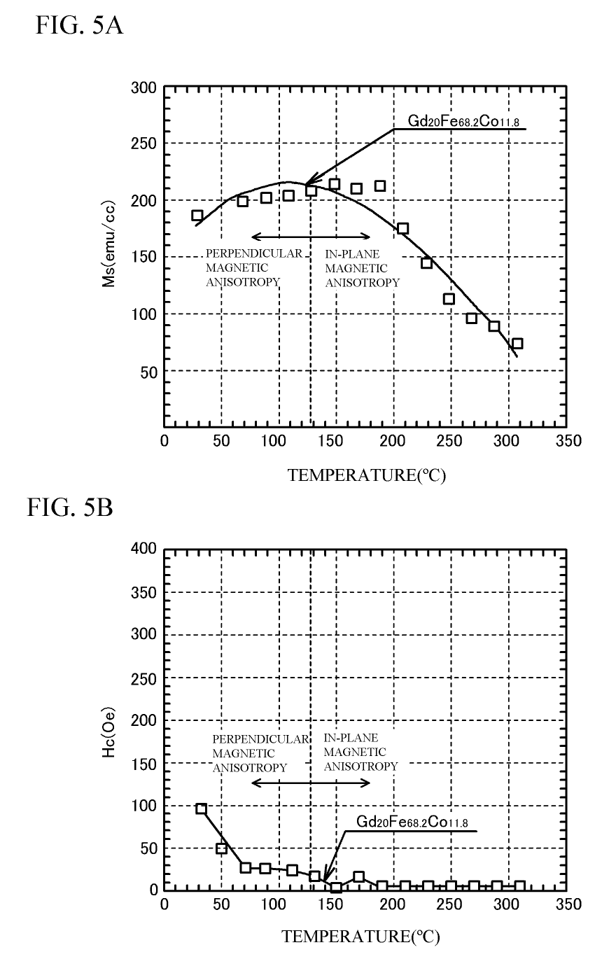

The amorphous metal layer of the second magnetic film 104 may be made of GdFeCo. In concrete, the amorphous metal layer may be made of Gd₂₀Fe_{68.2}Co_{11.8} (the inferior numeral indicates atomic percentage) in the embodiment. A magnetization easy axis of Gd₂₀Fe_{68.2}Co_{11.8} transits from a perpendicular direction to an in-plane direction at around 130 degrees C., as illustrated in FIG. 5A. As illustrated in FIG. 5B, magnetic coercive force (Hc) is very small and is equal to 100 (Oe) or less, even if the magnetization easy axis is in the perpendicular direction (at 130 degrees C. or less).

In the embodiment, the first magnetic film 102 is exchange-coupled and magnetically coupled to the second magnetic film 104 having perpendicular magnetic anisotropy in the above-mentioned lamination structure. Thus, the first magnetic film 102 expresses perpendicular magnetic anisotropy, as illustrated in FIG. 4A.

Non-patent document (G Tatara & H. Kohno, Phys. Rev. Lett., 92, 086601 (2004)) discloses that threshold current density (JC) required for driving the magnetic wall with current is expressed with Expression (1).

Jc=(e·S²/a³·h)·K⊥·λ (1)

“e” indicates elementary electrical charge. “Jc” indicates threshold current density. “a” indicates lattice constant. “h” indicates Plank's constant. “K⊥” indicates magnetic anisotropy in magnetization difficult direction. “λ” indicates magnetic wall width. “S²” indicates unit vector of spin.

In accordance with Expression (1), the threshold current density “Jc” is proportional to the magnetic wall width “λ”. It is therefore possible to reduce the threshold current density “Jc” by reducing the magnetic wall width “λ”.

The magnetic wall width “λ” may be expressed by Expression (2).

λ=2^{1/2}·π·(A/Kᵤ)^{1/2} (2)

“A” indicates exchange constant. “Kᵤ” indicates uniaxial magnetic anisotropy. The exchange constant “A” and the uniaxial magnetic anisotropy “Kᵤ” are a material constant. Therefore, “λ” is determined uniquely, when the material of the magnetic thin line 12 is determined. In the embodiment, the material of the magnetic thin line 12 is a thin line material having a line width of nanometer order and having in-plane magnetic anisotropy. Therefore, the magnetic wall width may be approximately the same as the thin line width.

On the other hand, the magnetic wall width “λ” is inversely proportional to “Ku”, in Expression (2). However, in general, “Kᵤ” of a material having perpendicular magnetic anisotropy is higher than that of a material having in-plane magnetic anisotropy by more than 10² (double digit). That is, “λ” and “Jc” of the perpendicular magnetic anisotropy material are equal to or less than 1/10 of those of the in-plane magnetic anisotropy material, with reference to Expressions (1) and (2). This is because “Ku” of a perpendicular magnetic anisotropy film of CoCrPt is 2×10⁵ (J/m³) while conventional in-plane magnetic anisotropy film Ni₈₁Fe₁₉ is −2×10³ (J/m³).

In the embodiment, the first magnetic film 102 and the second magnetic film 104 have the lamination structure, and the perpendicular magnetic anisotropy is added to the first magnetic film 102 having the in-plane magnetic anisotropy. Therefore, an increase of the uniaxial magnetic anisotropy “Kᵤ” is expected. And, reduction of the magnetic wall width “λ” and great reduction of the threshold current density “Jc” are expected.

The second magnetic film (amorphous metal layer) 104 is made of GdFeCo in the above-mentioned description. The material of the second magnetic film 104 is not limited. The second magnetic film (amorphous metal layer) 104 may be made of TbFeCo. The material (TbFeCo) has the same effect as GdFeCo.

In accordance with the embodiment, the magnetic thin line 12 has the lamination structure in which the first magnetic film (ferromagnetic metal layer) 102 having in-plane magnetic anisotropy and the second magnetic film (amorphous metal layer) 104 having perpendicular magnetic anisotropy are laminated, and each of the magnetic films are exchange-connected. Thus, the first magnetic film 102 expresses perpendicular magnetic anisotropy. Therefore, the uniaxial magnetic anisotropy “Kᵤ” of the first magnetic film 102 is increased. And the magnetic wall width “λ” may be reduced, or the threshold current density “Jc” may be reduced greatly. Further, the current consumption during the magnetic wall movement may be reduced.

In the embodiment, the second magnetic film 104 is made of the amorphous metal layer. Therefore, the second magnetic film 104 expresses perpendicular magnetic anisotropy even if a foundation layer (orientational control layer) is not provided. If a foundation layer is provided, electrical current is provided to the foundation layer. This may cause a loss in the electrical current or degradation in spin injection efficiency. It is, however, possible to restrain the electrical current loss and the degradation of the spin injection efficiency or to reduce the current consumption during the magnetic wall movement, with use of the amorphous metal layer.

It is gradually identified that magnetic wall driving current is increased when coercive force (Hc) of a magnetic thin line is increased. Coercive force of the amorphous metal layer in the embodiment (Gd₂₀Fe_{68.2}Co_{11.8}) is very small and is 100 (Oe) even if the amorphous metal layer has perpendicular magnetic anisotropy (at approximately 130 degrees C. or less). It is therefore possible to keep the magnetic wall driving current low.

Further, GdFeCo (Gd20Fe68.8Co11.8 in the embodiment) has perpendicular magnetic anisotropy in a wide temperature range as illustrated in FIG. 5A. Therefore, GdFeCo is suitable for a material of a storage or a memory of spin injection magnetic wall movement type.

The effect of the case where the magnetic thin line is made of only perpendicular magnetic anisotropy material is obtained in the case of the embodiment where the magnetic thin line includes the in-plane magnetic anisotropy material and the perpendicular magnetic anisotropy material. The embodiment is particularly effective in a case where the perpendicular magnetic anisotropy material is expensive or in a case where there are few types of the perpendicular magnetic anisotropy material or available material is limited, because used amount of the perpendicular magnetic anisotropy material is reduced compared to the conventional magnetic thin line.

In the embodiment, the material of the second layer is Gd20Fe68.2Co11.8. However, the material is not limited. Variable material or variable proportion may be selected for the material of the second layer according to the use condition of the magnetic memory device 100. For example, Gd₂₀Fe₈₀, Gd₃₂Fe₆₈, or Gd₃₂Fe₅₈Co₁₀ may be used.

In the embodiment, the first magnetic film (in-plane magnetic anisotropy) is laminated on the second magnetic film (perpendicular magnetic anisotropy). The lamination structure is not limited. For example, the second magnetic film may be laminated on the first magnetic film. The lamination structure may be the first magnetic film/the second magnetic film/the first magnetic film, the second magnetic film/the first magnetic film/the second magnetic film, or [the first magnetic film/the second magnetic film]ₙ (“n” is a number of lamination cycles). The in-plane magnetic anisotropy material expresses perpendicular magnetic anisotropy when the in-plane magnetic anisotropy material is magnetically connected to the perpendicular magnetic anisotropy material by exchange connection, even if any of the above-mentioned lamination structures are used. Therefore, the effect of the embodiment may be obtained.

In the embodiment, the second magnetic film 104 is made of amorphous metal film. The structure is not limited. The second magnetic film 104 may be made of crystalline alloy film. The crystalline alloy film may be one of CoPt, FePt, [Co/Pt]ₘ [Fe/Pt]ₘ (“m” is a number of lamination cucles), and CoCrPt.

In this case, the second magnetic film 104 needs a foundation layer such as Ta or Ru for perpendicular magnetic anisotropy. The consumption current may be increased or the spin injection efficiency may be degraded because the magnetic wall driving current is provided to the foundation layer. However, in the structure, the first magnetic film 102 having in-plane magnetic anisotropy and the second magnetic film 104 having perpendicular magnetic anisotropy are laminated. The magnetic wall driving current may be reduced, compared to a conventional magnetic thin line not having the lamination structure.

In the embodiment, the magnetic thin line is used in the magnetic memory device illustrated in FIG. 1. However, the magnetic thin line may be used in variable devices using magnetic thin lines such as a storage device of racetrack type or MRAM.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A magnetic thin line comprising:
a first magnetic film having in-plane magnetic anisotropy; and
a second magnetic film that is magnetically coupled to the first magnetic film and has perpendicular magnetic anisotropy,
wherein, with the coupling of the first magnetic film and the second magnetic film, magnetic wall width of the first magnetic film is lower than a case where the first magnetic film is not magnetically coupled to the second magnetic film.

2. The magnetic thin line as claimed in claim 1, wherein the first magnetic film and the second magnetic film are magnetically coupled to each other with a lamination structure of one of the first magnetic film/the second magnetic film, the second magnetic film/the first magnetic film, the first magnetic film/the second magnetic film/the first magnetic film, the second magnetic film/the first magnetic film/the second magnetic film, and [the first magnetic film/the second magnetic film]ₙ (“n” is a number of lamination cycles).

3. The magnetic thin line as claimed in claim 1, wherein the second magnetic film is one of crystalline alloy film and amorphous metal film.

4. The magnetic thin line as claimed in claim 3, wherein material of the crystalline alloy film is one of CoPt, FePt, [Co/Pt]ₙ, [Fe/Pt]ₙ (“n” is a number of lamination cycles), and CoCrPt.

5. The magnetic thin line as claimed in claim 3, wherein material of the amorphous metal film does not need crystalline orientation control.

6. The magnetic thin line as claimed in claim 5, wherein material of the amorphous metal film is one of TbFeCo, GdFeCo.

7. The magnetic thin line as claimed in claim 1, wherein material of the first magnetic film is alloy including one of Fe, Ni, Co, or the alloy in which one of Al, Cu and Si, non-magnetic metal, is doped.

8. A memory device comprising:
a magnetic thin line that has a first magnetic film having in-plane magnetic anisotropy and a second magnetic film that is magnetically coupled to the first magnetic film and has perpendicular magnetic anisotropy;
a recording element that records information in the magnetic thin line; and
a re-generating element that re-generates the information recorded in the recording element,
wherein:
with the coupling of the first magnetic film and the second magnetic film, magnetic wall width of the first magnetic film is lower than a case where the first magnetic film is not magnetically coupled to the second magnetic film; and
the information is recorded or re-generated by shifting a magnetic wall separating magnetic sections formed in the magnetic thin line with electrical current.

9. The memory device as claimed in claim 8, wherein the first magnetic film and the second magnetic film are magnetically coupled to each other with a lamination structure of one of the first magnetic film/the second magnetic film, the second magnetic film/the first magnetic film, the first magnetic film/the second magnetic film/the first magnetic film, the second magnetic film/the first magnetic film/the second magnetic film, and [the first magnetic film/the second magnetic film]ₙ (“n” is a number of lamination cycles).

10. The memory device as claimed in claim 8, wherein the second magnetic film is one of crystalline alloy film and amorphous alloy film.

11. The memory device as claimed in claim 10, wherein material of the crystalline alloy film is one of CoPt, FePt, [Co/Pt]ₙ, [Fe/Pt]ₙ (“n” is a number of lamination cycles), and CoCrPt.

12. The memory device as claimed in claim 10, wherein material of the amorphous alloy film does not need crystalline orientation control.

13. The memory device as claimed in claim 12, wherein material of the amorphous alloy film is one of TbFeCo, GdFeCo.

14. The memory device as claimed in claim 8, wherein material of the first magnetic film is alloy including one of Fe, Ni, Co, or the alloy in which one of Al, Cu and Si, non-magnetic metal, is doped.
